(19) United States
(12) Patent Application Publication
(10) Pub. No.: US 2025/0374581 A1
(43) Pub. Date: Dec. 4, 2025

(54) MANUFACTURING METHOD OF POWER SEMICONDUCTOR DEVICES

(71) Applicant: SAMSUNG ELECTRONICS CO., LTD., Suwon-si (KR)

(72) Inventors: Mingu KO, Suwon-si (KR); Youngcheol Kim, Suwon-si (KR); Jongseob Kim, Suwon-si (KR); Younghwan Park, Suwon-si (KR); Taehun Kim, Suwon-si (KR); Gyeongseon Park, Suwon-si (KR); Jeongpyo Hong, Suwon-si (KR)

(73) Assignee: SAMSUNG ELECTRONICS CO., LTD., Suwon-si (KR)

(21) Appl. No.: 18/939,074

(22) Filed: Nov. 6, 2024

(30) Foreign Application Priority Data
Jun. 3, 2024 (KR) 10-2024-0072605

(51) Int. Cl. H01L 29/66; H01L 21/02; H01L 21/324; H01L 29/16; H01L 29/417; H01L 29/423

(52) U.S. Cl. CPC H10D 30/025; H01L 21/02337; H01L 21/324; H10D 62/8325; H10D 64/252; H10D 64/513; H10D 64/514

(57) ABSTRACT

A method of manufacturing a power semiconductor device includes forming a drift layer, a well region, and a source region to form a substrate structure, forming mask layers on upper and lower surfaces of the substrate structure, performing a first annealing process on the substrate structure, forming a preliminary gate insulating layer on the upper surface of the substrate structure, performing a second annealing process on the substrate structure, forming a preliminary gate electrode layer on the preliminary gate insulating layer, forming a gate insulating layer and a gate electrode layer, forming a dielectric layer on the gate electrode layer, forming a source electrode coupled with the source region, forming a drain electrode on the lower surface of the substrate, and performing a high-pressure annealing process using deuterium subsequent to at least one of the performing the second annealing process or the forming of the dielectric layer.

### CROSS-REFERENCE TO RELATED APPLICATIONS

This application claims benefit of priority under 35 U.S.C. § 119 to Korean Patent Application No. 10-2024-0072605, filed on Jun. 3, 2024, in the Korean Intellectual Property Office, the disclosure of which is incorporated by reference herein in its entirety.

### BACKGROUND

### 1. Field

The present disclosure relates generally to semiconductor devices, and more particularly, to a method of manufacturing a power semiconductor device.

### 2. Description of Related Art

Power semiconductor devices may refer to semiconductor devices that may operate in relatively high voltage and/or relatively high current environments. That is, the power semiconductor devices may be used in fields that may need high power switching, such as, but not limited to, power conversion, power converters, inverters, or the like. Consequently, power semiconductor devices may have design constraints that may include, but not be limited to, voltage resistance characteristics against relatively high voltages, as well as, relatively high-speed switching operations. Accordingly, power semiconductor devices using silicon carbide (SiC), which may have superior voltage resistance characteristics when compared to silicon (Si), may be researched.

### SUMMARY

One or more example embodiments of the present disclosure provide a method of manufacturing a power semiconductor device with improved electrical characteristics when compared to related power semiconductor devices.

According to an aspect of the present disclosure, a method of manufacturing a power semiconductor device includes forming a substrate structure by forming a drift layer of a first conductivity-type on a substrate, a well region of a second conductivity-type on the drift layer, and a source region of the first conductivity-type on the well region, forming mask layers on an upper surface and a lower surface of the substrate structure, performing a first annealing process on the substrate structure, forming a preliminary gate insulating layer on the upper surface of the substrate structure, performing a second annealing process on the substrate structure and the preliminary gate insulating layer using nitrogen monoxide (NO), forming a preliminary gate electrode layer on the preliminary gate insulating layer, forming a gate insulating layer and a gate electrode layer by patterning the preliminary gate insulating layer and the preliminary gate electrode layer, forming a dielectric layer on the gate electrode layer, forming a source electrode coupled with the source region, forming a drain electrode on the lower surface of the substrate, and performing a high-pressure annealing process using deuterium (D), subsequent to at least one of the performing the second annealing process or the forming of the dielectric layer. The substrate is of the first conductivity-type and includes silicon carbide (SiC).

According to an aspect of the present disclosure, a method of manufacturing a power semiconductor device includes forming a substrate structure by forming a drift layer of a first conductivity-type on a substrate of the first conductivity-type, forming a well region of a second conductivity-type on the drift layer, and forming a source region of the first conductivity-type on the well region, performing a first annealing process on the substrate structure, forming a preliminary gate insulating layer on an upper surface of the substrate structure, performing a second annealing process on the substrate structure and the preliminary gate insulating layer using nitrogen monoxide (NO), forming a gate electrode layer on the preliminary gate insulating layer, forming a dielectric layer on the gate electrode layer, forming a source electrode coupled with the source region, forming a drain electrode on a lower surface of the substrate, and performing a high-pressure annealing process using deuterium (D), at least one of prior to the forming the preliminary gate insulating layer, subsequent to the performing the second annealing process, subsequent to the forming the dielectric layer, or subsequent to the forming the source electrode.

According to an aspect of the present disclosure, a method of manufacturing a power semiconductor device includes forming a substrate structure by forming a drift layer of a first conductivity-type on a substrate of the first conductivity-type, forming a well region of a second conductivity-type on the drift layer, and forming a source region of the first conductivity-type on the well region, performing a first annealing process on the substrate structure, forming a preliminary gate insulating layer on an upper surface of the substrate structure, performing a second annealing process on the substrate structure and the preliminary gate insulating layer, forming a gate electrode layer on the preliminary gate insulating layer, forming a dielectric layer on the gate electrode layer, forming a source electrode coupled with the source region, forming a drain electrode on a lower surface of the substrate, and performing a high-pressure annealing process using deuterium (D), subsequent to at least one of the performing of the second annealing process, the forming of the dielectric layer, or the forming of the source electrode.

Additional aspects may be set forth in part in the description which follows and, in part, may be apparent from the description, and/or may be learned by practice of the presented embodiments.

### BRIEF DESCRIPTION OF DRAWINGS

The above and other aspects, features, and advantages of certain embodiments of the present disclosure may be more apparent from the following description taken in conjunction with the accompanying drawings, in which:

FIG. 1 is a schematic cross-sectional view of a power semiconductor device, according to example embodiments;

FIGS. 2A and 2B are graphs illustrating a power semiconductor device, according to example embodiments;

FIG. 3 is a cross-sectional view illustrating a power semiconductor device, according to example embodiments;

FIG. 4 is a flowchart illustrating a method of manufacturing a power semiconductor device, according to example embodiments;

FIGS. 5A to 5M are views illustrating a process sequence of a method of manufacturing a power semiconductor device, according to example embodiments; and

FIGS. 6A and 6B are views illustrating processes of a method of manufacturing a power semiconductor device, according to example embodiments.

### DETAILED DESCRIPTION

The following description with reference to the accompanying drawings is provided to assist in a comprehensive understanding of embodiments of the present disclosure defined by the claims and their equivalents. Various specific details are included to assist in understanding, but these details are considered to be exemplary only. Therefore, those of ordinary skill in the art may recognize that various changes and modifications of the embodiments described herein may be made without departing from the scope and spirit of the disclosure. In addition, descriptions of well-known functions and structures are omitted for clarity and conciseness.

With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as “A or B,” “at least one of A and B,” “at least one of A or B,” “A, B, or C,” “at least one of A, B, and C,” and “at least one of A, B, or C,” may include any one of, or all possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” “coupled to,” “connected with,” or “connected to” another element (e.g., a second element), it means that the element may be coupled with the other element directly (e.g., wired), wirelessly, or via a third element.

It is to be understood that when an element or layer is referred to as being “over,” “above,” “on,” “below,” “under,” “beneath,” “connected to” or “coupled to” another element or layer, it may be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

The terms “upper,” “middle”, “lower”, and the like may be replaced with terms, such as “first,” “second,” third” to be used to describe relative positions of elements. The terms “first,” “second,” third” may be used to describe various elements but the elements are not limited by the terms and a “first element” may be referred to as a “second element”. Alternatively or additionally, the terms “first”, “second”, “third”, and the like may be used to distinguish components from each other and do not limit the present disclosure. For example, the terms “first”, “second”, “third”, and the like may not necessarily involve an order or a numerical meaning of any form.

As used herein, when an element or layer is referred to as “covering” or “overlapping” another element or layer, the element or layer may cover at least a portion of the other element or layer, where the portion may include a fraction of the other element or may include an entirety of the other element. Similarly, when an element or layer is referred to as “penetrating” another element or layer, the element or layer may penetrate at least a portion of the other element or layer, where the portion may include a fraction of the other element or may include an entire dimension (e.g., length, width, depth) of the other element.

Reference throughout the present disclosure to “one embodiment,” “an embodiment,” “an example embodiment,” or similar language may indicate that a particular feature, structure, or characteristic described in connection with the indicated embodiment is included in at least one embodiment of the present solution. Thus, the phrases “in one embodiment”, “in an embodiment,” “in an example embodiment,” and similar language throughout this disclosure may, but do not necessarily, all refer to the same embodiment. The embodiments described herein are example embodiments, and thus, the disclosure is not limited thereto and may be realized in various other forms.

It is to be understood that the specific order or hierarchy of blocks in the processes/flowcharts disclosed are an illustration of exemplary approaches. Based upon design preferences, it is understood that the specific order or hierarchy of blocks in the processes/flowcharts may be rearranged. Further, some blocks may be combined or omitted. The accompanying claims present elements of the various blocks in a sample order, and are not meant to be limited to the specific order or hierarchy presented.

As used herein, each of the terms “Al₂O₃”, “CoSi”, “GaAs”, “HfAlₓO_{y}”, “HfO₂”, “HfSiₓO_{y}”, “InAs”, “InP”, “La₂O₃”, “LaAlₓO_{y}”, “LaHfₓO_{y}”, “LaSi”, “MoSi₂”, “NiSi”, “NO”, “Pr₂O₃”, “SiC”, “SiGe”, “SiO₂”, “Ta₂O₃”, “TaN”, “TaSi₂”, “TiN”, “TiO₂”, “TiSi₂”, “WN”, “WSi₂”, “Y₂O₃”, “ZrO₂”, “ZrSiₓO_{y}”, and the like may refer to a material made of elements included in each of the terms and is not a chemical formula representing a stoichiometric relationship.

Hereinafter, various embodiments of the present disclosure are described with reference to the accompanying drawings.

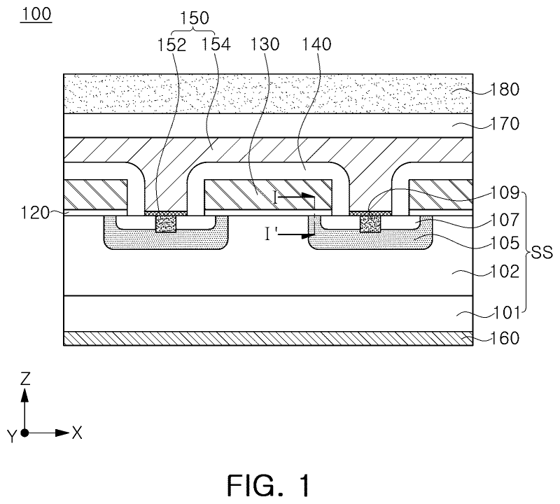

FIG. 1 is a schematic cross-sectional view of a power semiconductor device, according to example embodiments.

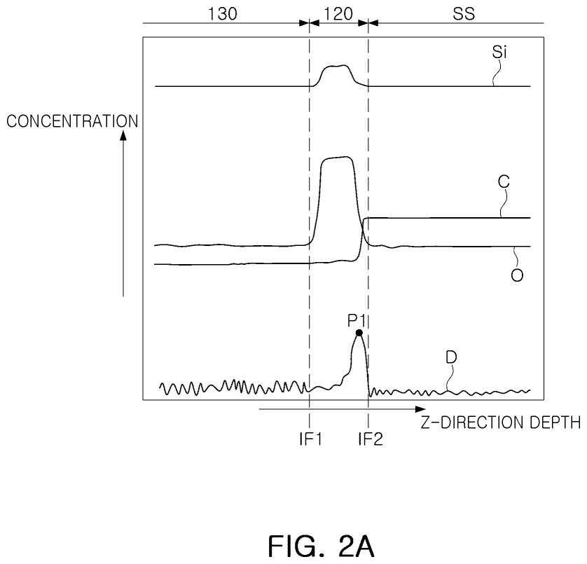

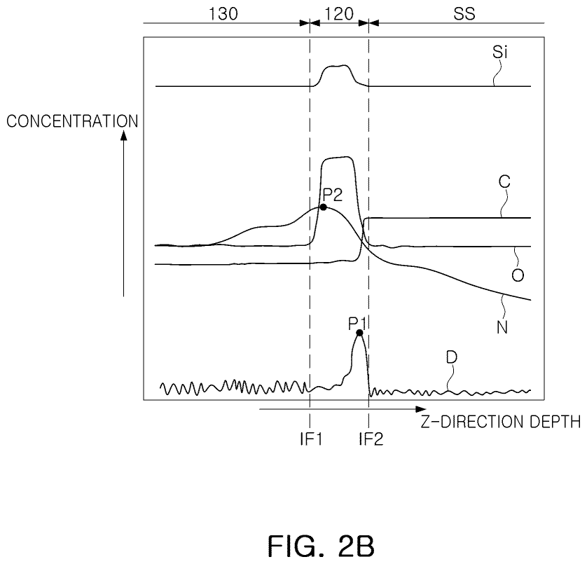

FIGS. 2A and 2B are graphs illustrating a power semiconductor device, according to example embodiments. FIGS. 2A and 2B illustrate concentration profiles of some elements in a region taken along line I-I′ of FIG. 1.

Referring to FIG. 1, a power semiconductor device 100 may include a substrate structure SS, gate electrodes 130 on the substrate structure SS, gate insulating layers 120 between the gate electrodes 130 and the substrate structure SS, dielectric layers 140 covering the gate electrodes 130, a source electrode 150 on the dielectric layers 140, a drain electrode 160 on a lower surface of the substrate 101, passivation layers (e.g., a first passivation layer 170 and a second passivation layer 180) on the source electrode 150.

The substrate structure SS may include a substrate 101, a drift layer 102 on the substrate 101, well regions 105 extending from an upper surface of the drift layer 102, a source region 107 extending from an upper surface of a well region 105 in each of the well regions 105, and well contact regions 109 on one side of the source regions 107.

The substrate 101 may have an upper surface extending in X and Y-directions. The substrate 101 may include a semiconductor material, which may include silicon carbide (SiC), for example. However, in some embodiments, the substrate 101 may include a group IV semiconductor material such as, but not limited to, silicon (Si), germanium (Ge), or a compound semiconductor material such as, but not limited to, silicon-germanium (SiGe), gallium arsenide (GaAs), indium arsenide (InAs), indium phosphide (InP), or the like.

The substrate 101 may be provided as a bulk wafer and/or an epitaxial layer. The substrate 101 may include first conductivity-type impurities, and thus may have a first conductivity type. In some embodiments, the first conductivity type may be an N-type, and the first conductivity-type impurities may be N-type impurities such as, but not limited to, nitrogen (N), phosphorus (P), or the like. In some embodiments, the first conductivity type may be a P-type and the first conductivity-type impurities may be P-type impurities such as, but not limited to, aluminum (Al).

The drift layer 102 may be disposed on the substrate 101. The drift layer 102 may include a semiconductor material, which may include silicon carbide (SiC), for example. The drift layer 102 may be an epitaxial layer grown on the substrate 101. The drift layer 102 may include the first conductivity-type impurities, and thus may have the first conductivity type. A concentration of the first conductivity-type impurities in the drift layer 102 may be lower than a concentration of the first conductivity-type impurities in the substrate 101. In some embodiments, the first conductivity-type impurities in the substrate 101 and the first conductivity-type impurities in the drift layer 102 may be substantially similar to or different from each other.

The well regions 105 may be disposed at a predetermined depth from an upper surface of the drift layer 102, and may be disposed to be spaced apart from each other by gate trenches GT in a horizontal direction (e.g., the X-direction). The well region 105 may include a semiconductor material, which may include, silicon carbide (SiC), for example. The well region 105 may be and/or may include a region having a second conductivity type, and may include second conductivity-type impurities. For example, the second conductivity type may be a P-type, and the second conductivity-type impurities may be P-type impurities such as, but not be limited to, aluminum (Al). In some embodiments, the well region 105 may include a plurality of regions having different doping concentrations.

The source regions 107 may be disposed at a predetermined depth from upper surfaces of the well regions 105. The source region 107 may include a semiconductor material, which may include silicon carbide (SiC), for example. The source region 107 may be and/or may include a region having the first conductivity type and may include first conductivity-type impurities as described above. A concentration of the first conductivity-type impurities in the source region 107 may be higher than a concentration of first conductivity-type impurities in the drift layer 102. However, the present disclosure is not limited thereto. That is, the concentration of the first conductivity-type impurities in the source region 107 and the concentration of the first conductivity-type impurities in the drift layer 102 may differ in various ways without departing from the scope of the present disclosure.

The well contact regions 109 may be disposed on the well regions 105 on one side of at least a portion of the source regions 107. The well contact region 109 may be disposed between the well region 105 and the source electrode 150, to allow a voltage from the source electrode 150 to be applied to the well region 105. The well contact region 109 may include a semiconductor material, which may include silicon carbide (SiC), for example. The well contact region 109 may be and/or may include a region having the second conductivity type and may include second conductivity-type impurities as described above. A concentration of the second conductivity-type impurities in the well contact region 109 may be higher than a concentration of the second conductivity-type impurities in the well region 105. However, the present disclosure is not limited thereto. That is, the concentration of the second conductivity-type impurities in the well contact region 109 and the concentration of the second conductivity-type impurities in the well region 105 may differ in various ways without departing from the scope of the present disclosure.

The gate electrodes 130 may be disposed on the substrate structure SS, and may be disposed on one end portions of the source regions 107, and on the well regions 105 outside the source regions 107. The gate electrode 130 may be disposed to overlap a portion of the source region 107 and a portion of the well region 105 in a vertical direction (e.g., Z-direction). The gate electrode 130 may be spaced apart from the source region 107, the well region 105, and the drift layer 102 by the gate insulating layer 120.

The gate electrode 130 may include a conductive material, which may include a semiconductor material (e.g., doped polycrystalline silicon), a metal nitride (e.g., titanium nitride (TiN), tantalum nitride (TaN), or tungsten nitride (WN)), and/or a metal material (e.g., aluminum (Al), tungsten (W), molybdenum (Mo)), or the like. In some embodiments, the gate electrode 130 may be provided as two (2) or more layers.

The gate insulating layers 120 may be disposed on lower surfaces of the gate electrodes 130. The gate insulating layer 120 may extend onto the source region 107, the well region 105 outside the source region 107, and the drift layer 102. The gate insulating layer 120 may be disposed between the source region 107 and the gate electrode 130, between the well region 105 and the gate electrode 130, and between the drift layer 102 and the gate electrode 130.

The gate insulating layer 120 may include an oxide, a nitride, or a high-κ material. The high-κ material may refer to a dielectric material having a higher dielectric constant than a silicon dioxide (SiO₂). The high-κ material may be and/or may include at least one of aluminum oxide (Al₂O₃), tantalum oxide (Ta₂O₃), titanium oxide (TiO₂), yttrium oxide (Y₂O₃), zirconium oxide (ZrO₂), zirconium silicon oxide (ZrSiₓO_{y}), hafnium oxide (HfO₂), hafnium silicon oxide (HfSiₓO_{y}), lanthanum oxide (La₂O₃), lanthanum aluminum oxide (LaAlₓO_{y}), lanthanum hafnium oxide (LaHfₓO_{y}), hafnium aluminum oxide (HfAlₓO_{y}), or praseodymium oxide (Pr₂O₃). In some embodiments, the gate insulating layer 120 may be provided as two (2) or more layers.

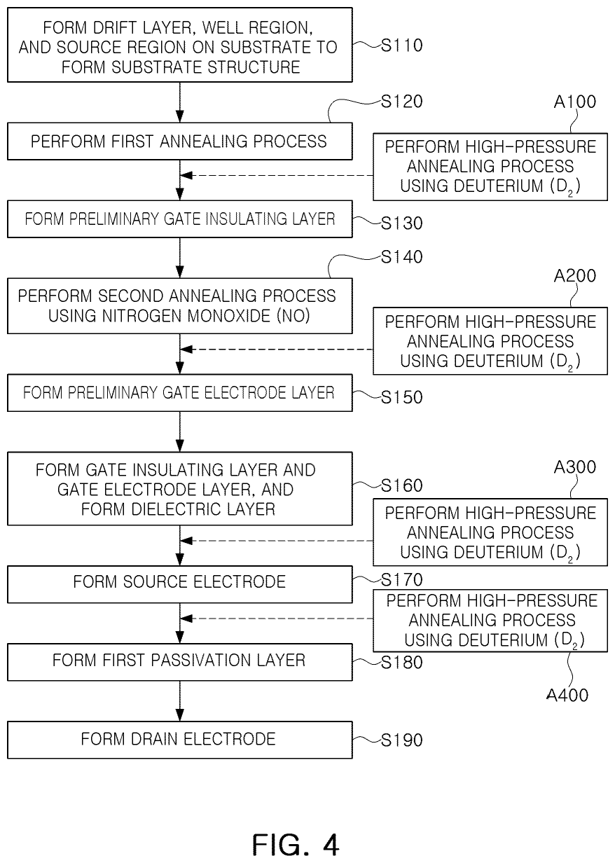

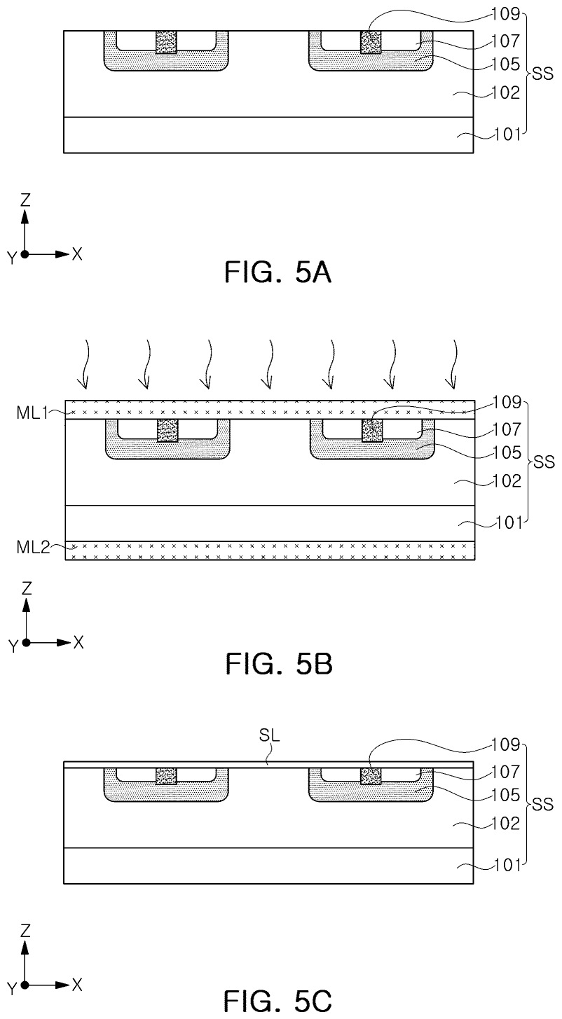

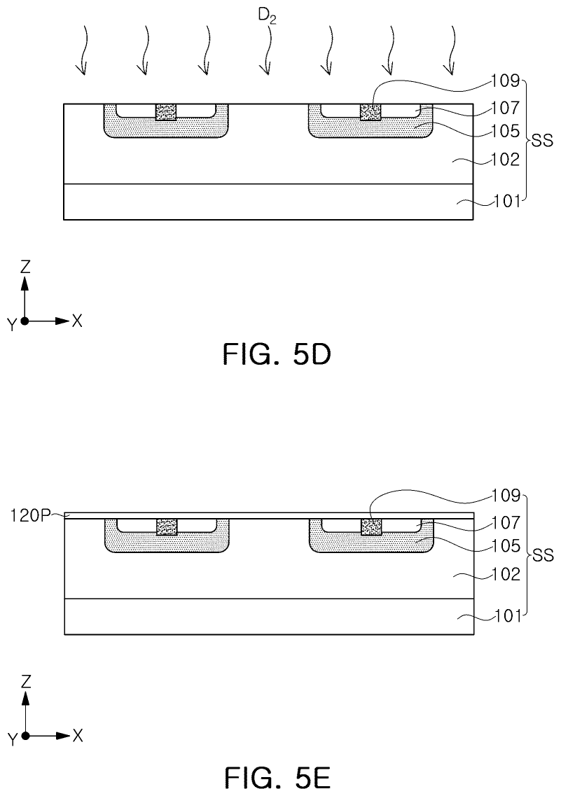

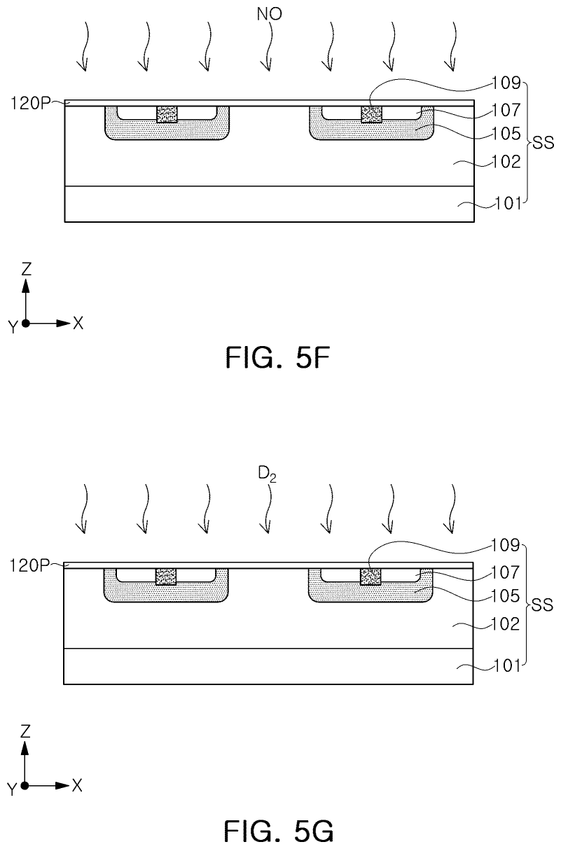

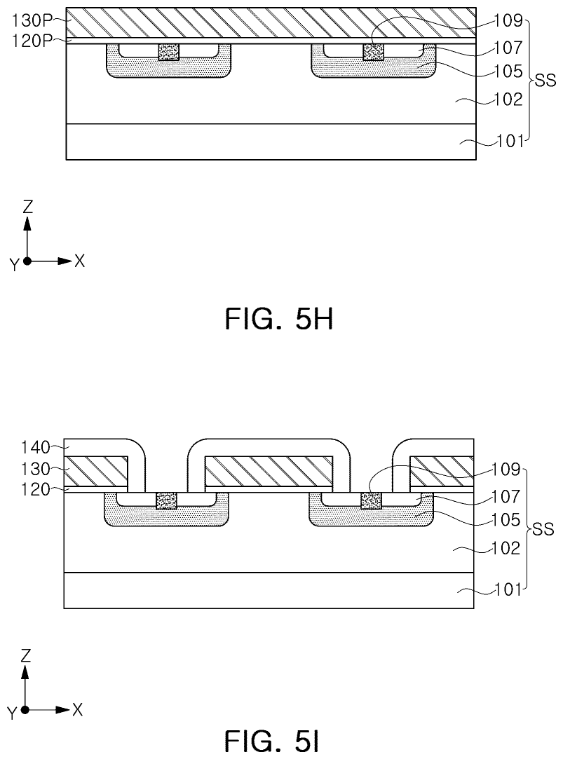

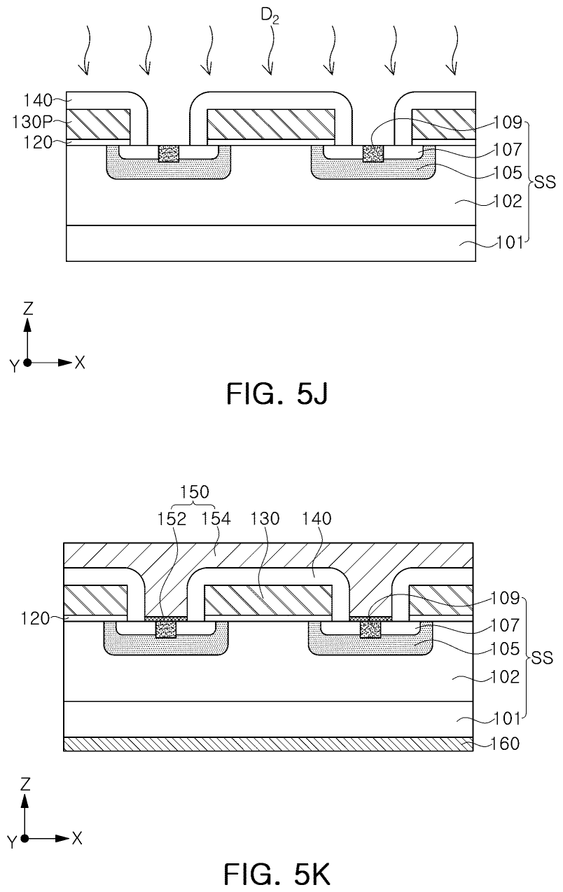

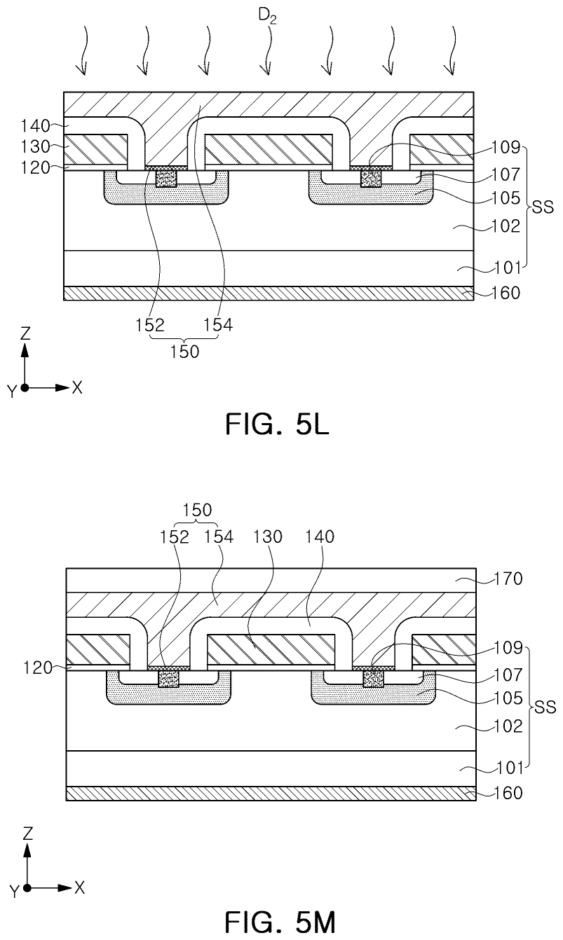

The gate insulating layer 120 may include a stabilized interface that may be formed by a high-pressure annealing process during a process of manufacturing the power semiconductor device 100. That is, the gate insulating layer 120 may be and/or may include a layer of which trap density on an interface with the substrate structure SS is reduced by a high-pressure annealing process using deuterium (D). Silicon carbide (SiC) may have more dangling bonds than silicon (Si), however, in the gate insulating layer 120, the dangling bonds may combine with deuterium (D) on the interface with silicon carbide (SiC) of the substrate structure SS to stabilize the interface. As a result, channel mobility of the power semiconductor device 100 may be improved when compared to related power semiconductor devices. The high-pressure annealing process is described with reference to FIGS. 4 to 5M.

FIGS. 2A and 2B illustrate concentration profiles of elements in an embodiment in which a gate electrode 130 includes polycrystalline silicon, a gate insulating layer 120 includes silicon dioxide (SiO₂), and a substrate structure SS includes silicon carbide (SiC). FIG. 2A illustrates concentration profiles of silicon (Si), oxygen (O), carbon (C), and deuterium (D), according to a gate electrode 130, a gate insulating layer 120, and a substrate structure SS, such as a well region 105. FIG. 2B further illustrates a concentration of nitrogen (N). However, the present disclosure is not limited in this regard. That is, relative magnitudes of concentrations between the elements in FIGS. 2A and 2B are not limited to those illustrated in FIGS. 2A and 2B.

Referring to FIG. 2A, a concentration of silicon (Si) and a concentration of oxygen (O) are illustrated to be relatively high in a gate insulating layer 120, and accordingly, a first interface IF1 and a second interface IF2 of the gate insulating layer 120 may be identified. In the gate insulating layer 120, deuterium (D) may have a first peak value P1, which may be the maximum value, at a position close (relatively near or within a certain threshold) to a substrate structure SS, based on a center in a thickness direction of the gate insulating layer 120. The first peak value P1 may be located closer to a second interface IF2 with the substrate structure SS than a first interface IF1 with a gate electrode 130, or may be located at the second interface IF2.

Referring to FIG. 2B, when annealing is performed using a nitrogen monoxide (NO) gas after forming a preliminary gate insulating layer (e.g., preliminary gate insulating layer 120P of FIG. 5F), nitrogen (N) may further exist in a gate insulating layer 120. A second peak value P2, which may be the maximum value for a concentration of nitrogen (N), may be closer to a first interface IF1 than a first peak value P1 of deuterium (D). For example, in a depth direction from a gate electrode 130, the first interface IF1, the second peak value P2, the first peak value P1, and a second interface IF2 may be located in sequence.

Therefore, a power semiconductor device 100 may include a gate insulating layer 120 stabilized by deuterium (D) to have improved electrical characteristics, when compared to related power semiconductor devices. For example, the power semiconductor device 100 may have an increased breakdown voltage of the gate insulating layer 120, a decreased threshold voltage, and a decreased sub-threshold swing, as compared to related power semiconductor devices in which a high-pressure annealing process may not have been performed.

The dielectric layers 140 may cover the gate electrodes 130, and may be disposed to expose at least a portion of the source regions 107 and at least a portion of the well contact regions 109. The dielectric layer 140 may cover a side surface of the gate electrode 130 and a side surface of the gate insulating layer 120. The dielectric layer 140 may include an insulating material, and may include at least one of silicon oxide (SiO), silicon nitride (SiN), or silicon oxynitride (SiON). In some embodiments, the dielectric layer 140 may include a high-material.

The source electrode 150 may be disposed on the dielectric layer 140, and may be electrically connected to the source regions 107 and the well contact regions 109. The source electrode 150 may include a metal-semiconductor compound layer 152 disposed on an interface contacting the source regions 107 and the well contact regions 109, and a conductive layer 154 on the metal-semiconductor compound layer 152. The metal-semiconductor compound layer 152 may include a metal element and a semiconductor element, and may include, but not be limited to, at least one of titanium silicide (TiSi₂), cobalt silicide (CoSi), molybdenum silicide (MoSi₂), lanthanum silicide (LaSi), nickel silicide (NiSi), tantalum silicide (TaSi₂), or tungsten silicide (WSi₂). The conductive layer 154 may be formed of a metal material, such as, but not limited to, at least one of nickel (Ni), aluminum (Al), titanium (Ti), silver (Ag), vanadium (V), tungsten (W), cobalt (Co), molybdenum (Mo), copper (Cu), or ruthenium (Ru).

The drain electrode 160 may be disposed on the lower surface of the substrate 101, and may be electrically connected to the substrate 101. The drain electrode 160 may include a metal material, such as, but not limited to, at least one of nickel (Ni), aluminum (Al), titanium (Ti), silver (Ag), vanadium (V), or tungsten (W). In some embodiments, the drain electrode 160 may also include a metal-semiconductor compound layer, which may be similar to the source electrode 150.

The first and second passivation layers 170 and 180 may be sequentially stacked on the source electrode 150. The first passivation layer 170 may include an insulating material, and may include at least one of silicon oxide (SiO), silicon nitride (SiN), or silicon oxynitride (SiON). The second passivation layer 180 may include an insulating material, such as, but not limited to, photosensitive polyimide (PSPI).

Although the power semiconductor device 100 has been illustrated as a metal oxide semiconductor field effect transistor (MOSFET), the present disclosure is not limited in this regard. For example, the gate insulating layer 120 may also be applied to a super junction MOSFET, a double trench MOSFET, an insulated gate bipolar transistor (IGBT) device, or the like. As another example, when the power semiconductor device is an IGBT, the substrate 101 may have the second conductivity type.

In the description of the following embodiments, descriptions overlapping those described above with reference to FIGS. 1 to 2B may be omitted for the sake of brevity.

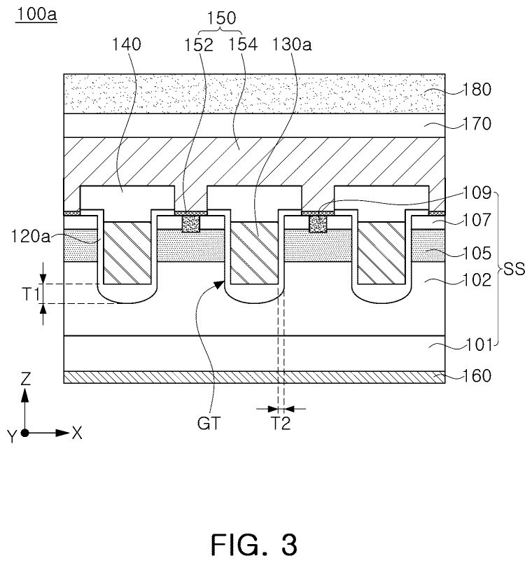

FIG. 3 is a cross-sectional view illustrating a power semiconductor device, according to example embodiments.

Referring to FIG. 3, in a power semiconductor device 100a, gate insulating layers 120a and gate electrodes 130a may be disposed in gate trenches GT. The gate trenches GT may extend from upper surfaces of source regions 107 through the source regions 107 and well regions 105 into a drift layer 102. A gate trench GT may completely penetrate a well region 105, and a lower end of the gate trench GT may be located in the drift layer 102. A depth to which the gate trench GT extends into the drift layer 102 may be changed in various embodiments. For example, in some embodiments, the lower end of the gate trench GT may be located on an upper surface of the drift layer 102. A gate insulating layer 120a and a gate electrode 130a may be disposed in the gate trench GT.

In some embodiments, a field relaxation layer formed by doping a portion of the drift layer 102 may be further disposed along a portion of an outer surface of the gate trench GT. The field relaxation layer may be located in the drift layer 102, and may extend along a bottom surface of the gate trench GT. The field relaxation layer may be and/or may include a region having the same conductivity-type as the well region 105 (e.g., the second conductivity-type) and may include impurities of the second conductivity-type.

The gate insulating layer 120a may be disposed on a side wall and the bottom surface of the gate trench GT. The gate insulating layer 120a may have a non-uniform thickness. For example, the gate insulating layer 120a may have a first thickness T1 on the bottom surface of the gate trench GT and a second thickness T2, smaller than the first thickness T1, on the side wall of the gate trench GT. The gate insulating layer 120a may include a region under the gate electrode 130a of which thickness in the Z-direction gradually decreases toward both sides from a center of the gate trench GT. The gate insulating layer 120a may have a relatively large thickness on the bottom surface of the gate trench GT, to mitigate an electric field formed in the drift layer 102 by the gate electrode 130a and/or to prevent destruction of the gate insulating layer 120a. In embodiments, a shape of a lower region of the gate trench GT, a resulted shape and thickness of the gate insulating layer 120a, or the like may be changed in various manners.

As described above with reference to FIGS. 1 to 2B, the gate insulating layer 120a may be and/or may include a layer in which a trap density on an interface with a substrate structure SS may be reduced by the high-pressure annealing process using deuterium (D).

The gate electrode 130a may be disposed on the gate insulating layer 120a in the gate trench GT. The gate electrode 130a may overlap the drift layer 102, the well region 105, and the source region 107 in a horizontal direction (e.g., the X-direction). A lower surface of the gate electrode 130a may be located in the drift layer 102. The lower surface of the gate electrode 130a may be located on a lower level than a lower surface of the well region 105, and an upper surface of the gate electrode 130a may be located on a lower level than an upper surface of the source region 107. In some embodiments, the upper surface of the gate electrode 130a may be located on a substantially similar level as or higher than the upper surface of the source region 107.

FIG. 4 is a flowchart illustrating a method of manufacturing a power semiconductor device, according to example embodiments.

FIGS. 5A to 5M are views illustrating a process sequence of a method of manufacturing a power semiconductor device, according to example embodiments. FIGS. 5A to 5M illustrate an embodiment of a method of manufacturing the power semiconductor device 100 of FIG. 1, and each thereof illustrate a region corresponding to FIG. 1.

Referring to FIGS. 4 and 5A, a drift layer 102 may be formed on a substrate 101, and well regions 105, source regions 107, and well contact regions 109 may be formed to form a substrate structure SS (operation S110).

The substrate 101 may be provided as a silicon carbide (SiC) wafer, for example. The drift layer 102 may be formed by epitaxial growth from the substrate 101. The drift layer 102 may be formed to include first conductivity-type impurities. The well region 105, the source regions 107, and the well contact regions 109 may be sequentially formed in the drift layer 102 by an ion implantation process. Second conductivity-type impurities may be implanted into the well region 105 and the well contact regions 109, and the first conductivity-type impurities may be implanted into the source regions 107.

Referring to FIGS. 4 and 5B, a first annealing process may be performed (operation S120).

The first annealing process may be performed on the substrate structure SS. Before the first annealing process, a first mask layer ML1 may be formed on an upper surface of the substrate structure SS and a second mask layer ML2 may be formed on a lower surface of the substrate structure SS. The first and second mask layers ML1 and ML2 may prevent silicon (Si) of the substrate structure SS from melting during the first annealing process. The first and second mask layers ML1 and ML2 may be and/or may include photoresist layers. However, the present disclosure is not limited in this regard.

The first annealing process may be performed at a relatively high temperature. In some embodiments, the first annealing process may be performed at a temperature of about 1600 degrees Celsius (° C.) to about 1800° C. and at a pressure of about 0.6 standard atmospheres (atm) to about 1 atm. For example, the first annealing process may be performed in an argon (Ar) atmosphere, and may be performed for about 40 to 80 minutes. Through the first annealing process, ions implanted through the ion implantation process described above may be activated and the substrate structure SS may be cured. After the first annealing process, the first and second mask layers ML1 and ML2 may be removed.

Referring to FIG. 5C, a sacrificial oxide layer SL may be formed on the upper surface of the substrate structure SS, and then removed.

The sacrificial oxide layer SL may be formed through an oxidation process. In some embodiments, the oxidation process may be performed at a temperature of about 1150° C. or higher (e.g., 1000° C. to 1300° C.) for about 15 minutes to about 25 minutes. The sacrificial oxide layer SL may be formed by consuming a portion of the substrate structure SS from the upper surface, for example, to a thickness of several nanometers.

The sacrificial oxide layer SL may be removed by, for example, a wet etching process. As a result, a region damaged by the ion implantation process may be removed on the upper surface of the substrate structure SS. In some embodiments, the wet etching process may be omitted. After removal of the sacrificial oxide layer SL, a field oxide layer may be formed on edge regions of the substrate structure SS. In some embodiments, the edge regions may include a junction termination extension (JTE) region.

Referring to FIGS. 4 and 5D, a high-pressure annealing process may be performed using deuterium (D) (operation A100).

The high-pressure annealing process may be performed on a structure being manufactured including the substrate structure SS and the field oxide layer. In some embodiments, the high-pressure annealing process may be performed at a temperature range of about 400° C. to about 700° C. and a high pressure range of about 10 atm to about 20 atm. The high-pressure annealing process may be performed in a deuterium (D) atmosphere and may be performed for about 40 to 80 minutes.

Through the high-pressure annealing process, dangling bonds on an interface of silicon carbide (SiC) forming the substrate structure SS may be coupled with deuterium (D) to stabilize the interface. When a dangling bond is coupled with deuterium (D), a bonding force may be similar, as compared to when a dangling bond is coupled with hydrogen (H). However, since deuterium (D) has a larger mass than hydrogen (H), the deuterium (D) may not diffuse and escape during an operation of the power semiconductor device, which may maintain a more stable interface than when a dangling bond is coupled with hydrogen (H). In some embodiments, the high-pressure annealing process may be performed using hydrogen (H) instead of deuterium (D).

In some embodiments, operation A100 may be omitted. For example, operation A100 may be performed only when a preliminary gate insulating layer 120P is formed through a deposition process, as described with reference to FIG. 5E.

Referring to FIGS. 4 and 5E, a preliminary gate insulating layer 120P may be formed on the upper surface of the substrate structure SS (operation S130).

The preliminary gate insulating layer 120P may be formed on an upper surface of the drift layer 102, upper surfaces of the well regions 105, upper surfaces of the source regions 107, and upper surfaces of the well contact regions 109. The preliminary gate insulating layer 120P may be formed by a deposition process or an oxidation process, such as, but not limited to, a thermal oxidation process. For example, the preliminary gate insulating layer 120P may be formed to have a thickness of about 40 nm to about 50 nm.

Referring to FIGS. 4 and 5F, a second annealing process may be performed (operation S140).

The second annealing process may be performed on a structure being manufactured including the substrate structure SS and the preliminary gate insulating layer 120P. The second annealing process may be performed, for example, at a temperature range of about 1000° C. to about 1200° C. and a pressure range of about 0.6 atm to about 1 atm. For example, the second annealing process may be performed in a nitrogen monoxide (NO) atmosphere and may be performed for about 20 to 100 minutes. Through the second annealing process, an interface between the substrate structure SS and the preliminary gate insulating layer 120P may be partially passivated, and clusters formed due to carbon (C) of the substrate structure SS may be removed.

Referring to FIGS. 4 and 5G, a high-pressure annealing process may be performed using deuterium (D) (operation A200).

The high-pressure annealing process may be performed on a structure being manufactured including the substrate structure SS and the preliminary gate insulating layer 120P. Process conditions for the high-pressure annealing process may be the same as those described above with reference to FIG. 5D. Through the high-pressure annealing process, dangling bonds on an interface between silicon carbide (SiC) forming the substrate structure SS and the preliminary gate insulating layer 120P may be coupled with deuterium (D), to stabilize the interface. In some embodiments, this operation (operation A200) may be omitted.

Referring to FIGS. 4 and 5H, a preliminary gate electrode layer 130P may be formed (operation S150).

The preliminary gate electrode layer 130P may be formed by depositing, for example, doped polycrystalline silicon on the preliminary gate insulating layer 120P. In some embodiments, the preliminary gate electrode layer 130P may be formed of a metal material.

Referring to FIGS. 4 and 5I, gate insulating layers 120 and gate electrode layers 130 may be formed, and dielectric layers 140 may be formed (operation S160).

The gate insulating layers 120 and the gate electrode layers 130 may be formed by patterning a stacked structure of the preliminary gate insulating layer 120P and the preliminary gate electrode layer 130P. As a result, a portion of the source regions 107 and a portion of the well contact regions 109 may be exposed between stacked structures of the gate insulating layer 120 and the gate electrode layer 130.

The dielectric layers 140 may be formed by forming a dielectric layer entirely on an upper surface of a structure being manufactured, and then removing a portion of the dielectric layer by an etching process to expose a portion of each of the source regions 107 and the well contact regions 109. The dielectric layer 140 may be formed to cover upper and side surfaces of the gate electrode 130, a side surface of the gate insulating layer 120, and a portion of an upper surface of the source region 107.

Referring to FIGS. 4 and 5J, a high-pressure annealing process may be performed using deuterium (D) (operation A300).

The high-pressure annealing process may be performed on a structure being manufactured including the substrate structure SS, the gate insulating layers 120, the gate electrode layers 130, and the dielectric layers 140. Process conditions for the high-pressure annealing process may be substantially similar and/or the same as those described with reference to FIG. 5D. Through the high-pressure annealing process, dangling bonds on an interface between silicon carbide (SiC) forming the substrate structure SS and the gate insulating layers 120 may be coupled with deuterium (D), to stabilize the interface. In some embodiments, operation A300 may be omitted.

Referring to FIGS. 4 and 5K, a source electrode 150 may be formed on the dielectric layers 140 (operation S170).

Metal-semiconductor compound layers 152 may be formed on an interface with the source regions 107 and the well contact regions 109. The metal-semiconductor compound layers 152 may be formed by a silicidation process, for example. A conductive layer 154 may be formed to cover the metal-semiconductor compound layers 152 and the dielectric layers 140. As a result, the source electrode 150 may be formed. The source electrode 150 may have a flat upper surface by a planarization process, or a curved upper surface.

Referring to FIGS. 4 and 5L, a high-pressure annealing process may be performed using deuterium (D) (operation A400).

The high-pressure annealing process may be performed on a structure being manufactured including the substrate structure SS, the gate insulating layers 120, the gate electrode layers 130, the dielectric layers 140, and the source electrode 150. Process conditions for the high-pressure annealing process may be substantially similar and/or the same as those described with reference to FIG. 5D. Through the high-pressure annealing process, dangling bonds on an interface between (SiC) forming the substrate structure SS and the gate insulating layers 120 may be coupled with deuterium (D), to stabilize the interface. In some embodiments, operation A400 may be omitted.

Referring to FIGS. 4 and 5M, a first passivation layer 170 may be formed (operation S180).

The first passivation layer 170 may be formed by depositing an insulating material on the source electrode 150.

Referring to FIGS. 1 and 4, a drain electrode 160 may be formed (operation S190) and a second passivation layer 180 may be formed.

The drain electrode 160 may be formed on a lower surface of the substrate 101. In some embodiments, the drain electrode 160 may be formed in another process operation. A grinding process may be further performed on the substrate 101 before forming the drain electrode 160. The second passivation layer 180 may be formed on the first passivation layer 170. As a result, the power semiconductor device 100 of FIG. 1 may be manufactured.

As described above with reference to FIGS. 4 to 5M, the high-pressure annealing process using deuterium (D) during a process of manufacturing the power semiconductor device 100 may be performed in at least one of operations A100, A200, A300, or A400. In some embodiments, the high-pressure annealing process may be performed in at least one of operations A200, A300, or A400. In some embodiments, the high-pressure annealing process may be performed in at least one of operations A200 or A300. For example, the high-pressure annealing process may be performed in operations A200 and A300. As another example, the high-pressure annealing process may be performed in operations A200 and A400, or may be performed in operations A300 and A400.

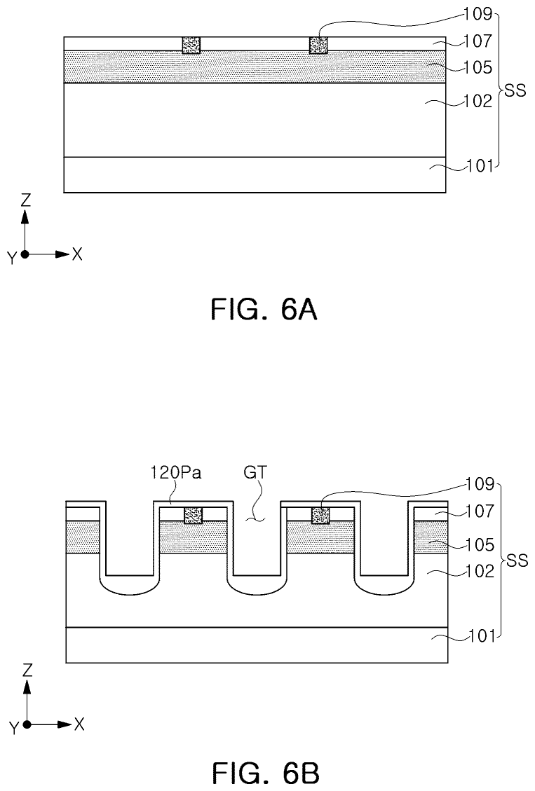

FIGS. 6A and 6B are views illustrating processes of a method of manufacturing a power semiconductor device, according to example embodiments. FIGS. 6A and 6B illustrate an embodiment of a method of manufacturing the power semiconductor device 100a of FIG. 3, and each thereof illustrate a region corresponding to FIG. 3.

Referring to FIGS. 4 and 6A, a drift layer 102 may be formed on a substrate 101, and a well region 105, source regions 107, and well contact regions 109 may be formed to form a substrate structure SS (operation S110).

Operation S110 may be performed similarly to the operation S110 described with reference to FIG. 5A. However, the well region 105 may be formed as a single layer, and arrangement of the source regions 107 and the well contact regions 109 may also differ.

Referring to FIGS. 4 and 6B, the well region 105 and the drift layer 102 may be partially removed to form gate trenches GT and a preliminary gate insulating layer 120Pa may be formed (operation S130).

In the present embodiment, the gate trenches GT may be formed before forming the preliminary gate insulating layer 120Pa. The gate trenches GT may be formed by forming a separate mask layer and then partially removing the source regions 107, the well region 105, and the drift layer 102. The gate trenches GT may be formed to completely penetrate the well region 105, and the drift layer 102 may be exposed through a bottom surface.

In some embodiments, before forming the preliminary gate insulating layer 120Pa, an annealing process may be further performed after removing the mask layer. The annealing process may include, for example, a hydrogen (H) annealing process performed in a hydrogen (H) atmosphere and a high temperature annealing process. By the hydrogen (H) annealing process, the gate trenches GT may be smoothed, to relieve an angle of an inner surface and have a curved shape.

The preliminary gate insulating layer 120Pa may be formed by depositing a first insulating material in the gate trench GT and further forming a second insulating material on the bottom surface of the gate trench GT, to form a relatively thick insulating material on the bottom surface of the gate trench GT. The second insulating material may be substantially similar and/or the same as the first insulating material. For example, the second insulating material may be formed through a spin-on glass (SOG) process or a high temperature oxide (HTO) process. In some embodiments, the forming of the second insulating material may be omitted.

Other processes may be performed in the same manner as the processes described above with reference to FIGS. 4 to 5M. Therefore, during a process of manufacturing the power semiconductor device 100a, the high-pressure annealing process using deuterium (D) may be performed in at least one of operations A100, A200, A300, or A400.

A method of manufacturing a power semiconductor device with improved electrical characteristics may be provided by stabilizing an interface between the gate insulating layer and silicon carbide (SiC) through a high-pressure annealing process.

Various advantages and effects of the present disclosure are not limited to the above-described contents, and may be more easily understood through description of specific embodiments of the present disclosure.

While example embodiments have been illustrated and described above, it is to be understood to those skilled in the art that modifications and variations may be made without departing from the scope of the present disclosure as defined by the appended claims.

What is claimed is:

1. A method of manufacturing a power semiconductor device, comprising:
forming a substrate structure by forming a drift layer of a first conductivity-type on a substrate, a well region of a second conductivity-type on the drift layer, and a source region of the first conductivity-type on the well region, the substrate being of the first conductivity-type and comprising silicon carbide (SiC);
forming mask layers on an upper surface and a lower surface of the substrate structure;
performing a first annealing process on the substrate structure;
forming a preliminary gate insulating layer on the upper surface of the substrate structure;
performing a second annealing process on the substrate structure and the preliminary gate insulating layer using nitrogen monoxide (NO);
forming a preliminary gate electrode layer on the preliminary gate insulating layer;
forming a gate insulating layer and a gate electrode layer by patterning the preliminary gate insulating layer and the preliminary gate electrode layer;
forming a dielectric layer on the gate electrode layer;
forming a source electrode coupled with the source region;
forming a drain electrode on the lower surface of the substrate; and
performing a high-pressure annealing process using deuterium (D), subsequent to at least one of the performing the second annealing process or the forming of the dielectric layer.

2. The method of claim 1, wherein the performing of the high-pressure annealing process comprises:
performing the high-pressure annealing process subsequent to the performing of the second annealing process and prior to the forming of the gate electrode layer.

3. The method of claim 1, wherein the performing of the high-pressure annealing process comprises:
performing the high-pressure annealing process subsequent to the forming the dielectric layer and prior to the forming of the source electrode.

4. The method of claim 1, wherein the performing of the high-pressure annealing process comprises:
performing a first high-pressure annealing process subsequent to the performing of the second annealing process; and
performing a second high-pressure annealing process subsequent to the forming of the dielectric layer.

5. The method of claim 1, wherein the performing of the high-pressure annealing process comprises:
performing the high-pressure annealing process at a pressure in a range of 10 standard atmospheres (atm) to 30 atm.

6. The method of claim 1, wherein the performing of the high-pressure annealing process comprises:
performing the high-pressure annealing process at a temperature in a range of 400 degrees Celsius (° C.) to 700° C.

7. The method of claim 1, wherein the performing of the high-pressure annealing process comprises:
performing the high-pressure annealing process subsequent to the forming of the source electrode.

8. The method of claim 1, wherein the forming of the gate insulating layer comprises depositing a material forming the gate insulating layer, and
wherein the performing of the high-pressure annealing process comprises performing the high-pressure annealing process prior to the forming of the gate insulating layer.

9. The method of claim 1, wherein the performing of the high-pressure annealing process comprises:
performing the high-pressure annealing process at a lower temperature and a higher pressure than the performing of the first annealing process.

10. The method of claim 1, wherein the performing of the high-pressure annealing process comprises:
performing the high-pressure annealing process at a lower temperature and a higher pressure than the performing of the second annealing process.

11. The method of claim 1, wherein the gate insulating layer comprises deuterium (D), and
wherein, in the gate insulating layer, a concentration of the deuterium (D) has a peak value in a region closer to a first interface between the gate insulating layer and the well region than on a second interface between the gate insulating layer and the gate electrode layer, in a direction perpendicular to the upper surface of the substrate structure.

12. The method of claim 1, wherein the gate insulating layer comprises deuterium (D) and nitrogen (N), and
wherein, in the gate insulating layer, a first peak value of a first concentration of the deuterium (D) is closer to the well region than a second peak value of a second concentration of the nitrogen (N), in a direction perpendicular to the upper surface of the substrate structure.

13. A method of manufacturing a power semiconductor device, comprising:
forming a substrate structure by forming a drift layer of a first conductivity-type on a substrate of the first conductivity-type, forming a well region of a second conductivity-type on the drift layer, and forming a source region of the first conductivity-type on the well region;
performing a first annealing process on the substrate structure;
forming a preliminary gate insulating layer on an upper surface of the substrate structure;
performing a second annealing process on the substrate structure and the preliminary gate insulating layer using nitrogen monoxide (NO);
forming a gate electrode layer on the preliminary gate insulating layer;
forming a dielectric layer on the gate electrode layer;
forming a source electrode coupled with the source region;
forming a drain electrode on a lower surface of the substrate; and
performing a high-pressure annealing process using deuterium (D), at least one of prior to the forming the preliminary gate insulating layer, subsequent to the performing the second annealing process, subsequent to the forming the dielectric layer, or subsequent to the forming the source electrode.

14. The method of claim 13, wherein the performing of the high-pressure annealing process comprises:
performing the high-pressure annealing process at a lower temperature and a higher pressure than the performing of the first annealing process and the second annealing process.

15. The method of claim 13, wherein the performing of the first annealing process comprises:
performing the first annealing process at a higher temperature than the performing of the second annealing process.

16. The method of claim 13, further comprising:
at least partially removing the substrate structure to form gate trenches, prior to the forming of the preliminary gate insulating layer.

17. The method of claim 13, wherein the substrate, the drift layer, and the well region comprise silicon carbide (SIC).

18. A method of manufacturing a power semiconductor device, comprising:
forming a substrate structure by forming a drift layer of a first conductivity-type on a substrate of the first conductivity-type, forming a well region of a second conductivity-type on the drift layer, and forming a source region of the first conductivity-type on the well region;
performing a first annealing process on the substrate structure;
forming a preliminary gate insulating layer on an upper surface of the substrate structure;
performing a second annealing process on the substrate structure and the preliminary gate insulating layer;
forming a gate electrode layer on the preliminary gate insulating layer;
forming a dielectric layer on the gate electrode layer;
forming a source electrode coupled with the source region;
forming a drain electrode on a lower surface of the substrate; and
performing a high-pressure annealing process using deuterium (D), subsequent to at least one of the performing of the second annealing process, the forming of the dielectric layer, or the forming of the source electrode.

19. The method of claim 18, wherein the performing of the high-pressure annealing process comprises:
performing the high-pressure annealing process at least subsequent to the performing of the second annealing process.

20. The method of claim 18, wherein the performing of the high-pressure annealing process comprises performing the high-pressure annealing process using a first gas,
wherein the performing of the first annealing process comprises performing the first annealing process using a second gas,
wherein the performing of the second annealing process comprises performing the second annealing process using a third gas, and
wherein the first gas, the second gas, and the third gas are different gases from each other.
